(19) United States
(12) Patent Application Publication
(10) Pub. No.: US 2026/0055936 A1
(43) Pub. Date: Feb. 26, 2026

(54) HIGH-TRANSMITTANCE RADIATIVE COOLING PROTECTIVE FILM

(71) Applicant: MOGUANG NEW ENERGY TECHNOLOGY (SUZHOU) CO., LTD, Jiangsu (CN)

(72) Inventors: Linqi ZONG, Jiangsu (CN); Dexing KONG, Jiangsu (CN); Bin LYU, Jiangsu (CN)

(73) Assignee: MOGUANG NEW ENERGY TECHNOLOGY (SUZHOU) CO., LTD, Jiangsu (CN)

(21) Appl. No.: 19/375,266

(22) Filed: Oct. 31, 2025

Related U.S. Application Data
(63) Continuation-in-part of application No. PCT/CN2024/108773, filed on Jul. 31, 2024.

(30) Foreign Application Priority Data
Jun. 7, 2023 (CN) 202310668280.2

(51) Int. Cl. F25B 23/00; C23C 14/08; C23C 14/22

(52) U.S. Cl. CPC F25B 23/003; C23C 14/08; C23C 14/221

(57) ABSTRACT

A high-transmittance radiative cooling protective film, comprising a spectrum regulation and control layer, wherein the spectrum regulation and control layer comprises low-refractive-index materials and high-refractive-index materials which are alternately stacked, there are no less than six layers of the high-refractive-index materials, and there are no less than five layers of the low-refractive-index materials. According to the film, spectrum regulation and control are realized by means of the structural design of a multilayer film, the incidence of other energy bands of sunlight is effectively blocked while ensuring high visible light transmittance, and heat is emitted in the form of electromagnetic waves into a natural cold source of the universe by means of thermal infrared bands, thereby achieving radiative cooling effect to the maximum extent.

### CROSS-REFERENCE TO RELATED APPLICATION

This application is a continuation-in-part application of international application of PCT patent application PCT/CN2024/108773, filed on Jul. 31, 2024, which claims the priority benefit of China application serial no. 202310668280.2, filed on Jun. 7, 2023. The entirety of the above-mentioned patent application is hereby incorporated by reference herein and made a part of this specification.

### TECHNICAL FIELD

The present disclosure relates to a protective film, and in particular to a high-transmittance radiative cooling protective film and use thereof.

### BACKGROUND

With the growth of the global population and continuous social development, the issue of global warming is becoming increasingly severe, which in turn drives a growing demand for cooling energy. Traditional active cooling means rely on compression-based refrigeration systems. On the one hand, the systems consume a great amount of electricity and result in significant carbon dioxide; on the other hand, refrigerants used in compression cooling systems, such as Freon, can deplete the ozone layer, causing serious environmental issues. In sharp contrast to conventional cooling methods, radiative cooling is a passive cooling approach that emits heat into the cold outer space through thermal radiation. The Earth's atmosphere exhibits varying transmittances for electromagnetic waves at different wavelengths, with a particularly high transmittance in the 8-13 μm band, known as an “atmospheric window.” Therefore, an excellent radiative cooling surface should exhibit as high emissivity as possible in the 8-13 μm band while strongly reflecting solar radiation (0.3-2.5 μm), thereby achieving spontaneous cooling without consuming any energy. In summary, radiative cooling technology can save energy while mitigating the greenhouse effect and environmental pollution problems associated with conventional cooling.

With the development of nanophotonics and advanced fabrication technologies, photonic crystals and metamaterials have been pioneered as radiative cooling materials. Nanophotonic crystals refer to nanophotonic materials with various layered and metasurface structures formed by thin-film deposition or micro-nanofabrication techniques such as magnetron sputtering or electron-beam evaporation, on some semiconductor materials, thereby achieving selective high emissivity in specific mid-infrared bands.

Ordinary materials usually exhibit broad thermal emission spectra. In contrast, photonic materials can be designed to produce a controllable, narrowband thermal emission spectrum, which is particularly desirable for radiative cooling. As reported in the literature (Nature, 2014, 515(7528): 540-544), a radiative cooler was fabricated based on an integrated planar layered one-dimensional photonic crystal. The radiative cooler includes a photonic crystal composed of seven alternating layers of SiO₂ and HfO₂ deposited on a silver (Ag) mirror, where the SiO₂ layer exhibits extremely high emissivity in 8-13 μm mid-infrared band due to its phonon-polariton property; and the stacking of SiO₂ and HfO₂ layers further modulates the spectral emissivity in the mid-infrared band. In addition, the Ag mirror enhances the reflectivity of the multilayer film stack in the ultraviolet portion of solar radiation. Through the multilayered structure, the radiative cooler can reflect approximately 97% of solar radiation while exhibiting strong thermal emission within the atmospheric window, resulting in a cooling effect of 5° C. below ambient temperature and a cooling capacity of 40.1 W·m⁻² under a solar irradiance of 900 W·m⁻².

However, at present, radiative cooling materials are primarily applied to outdoor structures such as walls and roofs, and have rarely been integrated into display devices. This is because display devices impose more stringent spectral requirements on radiative cooling materials.

### SUMMARY

An objective of the present disclosure is to provide a radiative cooling film applicable to display devices. Based on this objective, a high-transmittance radiative cooling protective film is provided, which exhibits selective high emissivity in a mid-infrared band to achieve low-energy passive cooling, while possessing extremely high transmittance in a visible light band.

A technical solution adopted by the present disclosure is as follows: a high-transmittance radiative cooling protective film includes a spectrum regulation and control layer. The spectrum regulation and control layer includes high-refractive-index materials and low-refractive-index materials which are alternately stacked, the high refractive index material has at least six layers, and the low refractive index material has at least five layers. After light passes through the film, visible light has a transmittance exceeding 90%, near-infrared light has a reflectivity exceeding 80% to effectively block the near-infrared light, and mid-infrared light has an emissivity exceeding 95%.

As a preferred solution, the low-refractive-index materials in each layer are identical or different, and are selected from one or more of SiO₂, SiO, SiC, Al₂O₃, AlF₃, and MgF₂.

As a preferred solution, the high-refractive-index materials in each layer are identical or different, and are selected from one or more of TiO₂, Ti₃O₅, Ti₂O₃, ZrO₂, CeO₂ and HfO₂.

As a preferred solution, the spectrum regulation and control layer is composed of a non-metallic layer material.

As a preferred solution, both the low-refractive-index materials and the high-refractive-index materials are deposited by electron beam evaporation coating, and a coating process meets one or more of the following conditions:
a deposition rate of 0.1-1.0 nm/s;
a particle size of the materials of 1-20 mm during deposition;
a deposition temperature of 80-200° C.;
a vacuum level maintained at 1×10⁻²-1×10⁻⁴ Pa during deposition;
ion-assisted deposition used for deposition, with ion source energy parameters of a voltage of 150-220 V and a current of 3-6 A.

As a preferred solution, a top layer and a bottom layer of the spectrum regulation and control layer are both made of the high-refractive-index materials.

As a preferred solution, the spectrum regulation and control layer includes, in sequence from the bottom layer to the top layer, TiO₂, SiO, TiO₂, SiO, TiO₂, SiO, TiO₂, SiO, TiO₂, SiO, TiO₂, such that incident external light first passes through the top layer and then sequentially through each intermediate layer to the bottom layer.

As a preferred solution, the high-transmittance radiative cooling protective film further includes an organic encapsulation layer, and the organic encapsulation layer is a hydrophobic layer.

As a preferred solution, the spectrum regulation and control layer includes the following material layers arranged in sequence:
a TiO₂ material layer having a thickness of 10-20 nm;
a SiO material layer having a thickness of 20-50 nm;
a TiO₂ material layer having a thickness of 100-150 nm;
a SiO material layer having a thickness of 150-200 nm;
a TiO₂ material layer having a thickness of 80-110 nm;
a SiO material layer having a thickness of 150-200 nm;
a TiO₂ material layer having a thickness of 90-130 nm;
a SiO material layer having a thickness of 150-200 nm;
a TiO₂ material layer having a thickness of 90-130 nm;
a SiO material layer having a thickness of 20-50 nm; and
a TiO₂ material layer having a thickness of 10-20 nm.

In another aspect, the present disclosure provides use of the high-transmittance radiative cooling protective film. The protective film can be used as a screen film adhered onto an electronic product, especially a mobile phone screen, so as to provide a radiative cooling effect under outdoor conditions and prevent excessive temperature rise of the mobile phone. As shown in FIG. 1, the high-transmittance radiative cooling protective film includes an organic encapsulation layer, a substrate film, a radiative cooling layer, and an AB adhesive layer that are arranged in sequence, where the substrate film is a tempered glass film for mobile phone, which may be a commercially available tempered glass film for mobile phone. The radiative cooling layer is deposited on the tempered glass film for mobile phone, and the AB adhesive layer is used to attach the radiative cooling protective film onto the screen.

The present disclosure has the following beneficial effects: the protective film realizes spectrum regulation and control by means of the structural design of a multilayer film, the incidence of other energy bands of sunlight is effectively blocked while ensuring high visible light transmittance, and heat is emitted in the form of electromagnetic waves into a natural cold source of the universe by means of thermal infrared bands, thereby achieving radiative cooling effect to the maximum extent. Specifically, the high-transmittance radiative cooling protective film can achieve a transmittance for visible light exceeding 90%, a blocking ratio for near-infrared light exceeding 80%, and an emissivity for mid-infrared light exceeding 95%, thereby ultimately realizing a cooling effect of 5-10° C.

Through the multilayer film structure with alternately staked low-refractive-index materials and high-refractive-index materials, and by utilizing the interference effect of light, the stacking of different materials increases the transmission in some wavelength bands and enhances the reflection in other bands, thereby achieving spectrum regulation and control in specific wavelength ranges.

The protective film can be applied to almost any material surface for cooling by adhesion. In practical applications, it can be applied not only on outdoor building surfaces such as glass, walls, and roofs, but also in display devices such as electronic devices, making it an effective tool for energy conservation and emission reduction. In addition, an organic encapsulation layer is introduced, which enables the protective film to possess excellent anti-aging properties, as well as outstanding hydrophobic, anti-fouling, and wear-resistant performance during use.

### BRIEF DESCRIPTION OF THE DRAWINGS

FIG. 1 is a schematic structural diagram of a high-transmittance radiative cooling protective film according to the present disclosure.

FIG. 2 is a structural diagram of a spectrum regulation and control layer according to the present disclosure.

FIG. 3 shows a transmittance of glass in visible and near-infrared bands before and after film deposition.

FIG. 4 shows an emissivity of glass in a mid-infrared band before and after film deposition.

FIG. 5 shows a cooling performance test of glass before and after film deposition.

FIG. 6 shows a contact angle between glass with an organic encapsulation layer and water.

FIG. 7 shows a contact angle between glass without an organic encapsulation layer and water.

### DETAILED DESCRIPTIONS OF THE EMBODIMENTS

The present disclosure will be further explained in detail below in conjunction with specific embodiments. However, it should be understood that the scope of protection of the present disclosure is not limited by the specific embodiments.

The high-transmittance radiative cooling protective film of the present disclosure includes a substrate film and a spectrum regulation and control layer. The spectrum regulation and control layer is deposited on the substrate film. The spectrum regulation and control layer includes high-refractive-index materials and low-refractive-index materials which are alternately stacked, the high refractive index material has at least six layers, and the low refractive index material has at least five layers. By alternately arranging the two materials having different refractive indexes, a refraction angle of light in the film is adjusted, thereby regulating a transmission path of light of different wavelength ranges in the film, and achieving regulation of the spectral properties. After passing through the film, visible light exhibits a transmittance exceeding 90%, near-infrared light has a blocking ratio exceeding 80%, and mid-infrared light exhibits an emissivity exceeding 95%. An organic encapsulation layer is made of a fluorine-containing organic material and is implemented using electron beam evaporation coating. The encapsulation layer has a preferred thickness of 5-40 nm, a preferred evaporation current of 30-200 mA, and a deposition rate of 0.3-1.0 nm/s.

The low-refractive-index materials and the high-refractive-index materials of the present disclosure are both ceramic materials without a metal layer, thereby simplifying the film design. Reflectivity, transmittance, and emissivity are regulated by regulating a thickness of each ceramic layer and the deposition process. The difference in refractive index between the low-refractive-index materials and the high-refractive-index materials falls within a range of 0.5-0.9.

The low-refractive-index materials in the spectrum regulation and control layer may be identical or different, and may be a single material or a plurality of materials. The low-refractive-index materials may be partially identical or entirely identical, and are selected from one or more of SiO₂, SiO, Al₂O₃, AlF₃, and MgF₂. The high-refractive-index materials may be identical or different, or may also be either partially or entirely identical, and is selected from one or more of TiO₂, Ti₃O₅, Ti₂O₃, ZrO₂, CeO₂, and HfO₂. To simplify the process, it is preferred that all low-refractive-index materials are identical, and all high-refractive-index materials are identical.

The substrate film of the present disclosure may be a tempered glass film for mobile phone. The high-transmittance radiative cooling protective film further includes an organic encapsulation layer and an AB adhesive layer. The organic encapsulation layer and the spectrum regulation and control layer are deposited on opposite sides of the substrate film by evaporation or sputtering. Preferably, electron beam evaporation coating is employed, as the film structure formed by the evaporation is dense and highly stable. During the deposition process, a particle size of the materials may be 1-20 mm, a temperature range of film formation is 80-200° C., a vacuum degree is maintained at 1×10⁻²-1×10⁻⁴ Pa, and the deposition rate is determined according to the film thickness. When the film thickness is less than 50 nm, the deposition rate is preferably 0.1-0.5 nm/s; when the film thickness is greater than or equal to 50 nm, the deposition rate is preferably 0.6-1.0 nm/s. This configuration not only facilitates precise control of the film thickness but also improves the stability of film formation.

To ensure a dense bond between the multilayer films, ion-assisted deposition is used for deposition of each material. The ion source energy parameters are as follows: a voltage of 150-220 V and a current of 3-6 A.

The protective film of the present disclosure is preferably arranged in the following order from a glass substrate outward: TiO₂, SiO, TiO₂, SiO, TiO₂, SiO, TiO₂, SiO, TiO₂, SiO, and TiO₂, with a thickness of each film layer is as follows:
a TiO₂ material layer having a thickness of 10-20 nm;
a SiO material layer having a thickness of 20-50 nm;
a TiO₂ material layer having a thickness of 100-150 nm;
a SiO material layer having a thickness of 150-200 nm;
a TiO₂ material layer having a thickness of 80-110 nm;
a SiO material layer having a thickness of 150-200 nm;
a TiO₂ material layer having a thickness of 90-130 nm;
a SiO material layer having a thickness of 150-200 nm;
a TiO₂ material layer having a thickness of 90-130 nm;
a SiO material layer having a thickness of 20-50 nm; and
a TiO₂ material layer having a thickness of 10-20 nm.

The present disclosure will be further illustrated with the following specific embodiments.

### Example 1

A high-transmittance radiative cooling protective film includes an organic encapsulation layer 1, a substrate film 2, a spectrum regulation and control layer 3, and an AB adhesive layer 4. The organic encapsulation layer 1 is a fluorine-containing organic material layer. The substrate film is a film for mobile phone, which may be a commercially available tempered glass film or flexible film for mobile phone, and may have high light transmittance. In this Example, the spectrum regulation and control layer 3 is formed by depositing on the tempered glass film for mobile phone. The AB adhesive layer 4 is configured to bond the radiative cooling protective film onto a mobile phone. The spectrum regulation and control layer 3 includes an 11-layer structure, the high-refractive-index materials and the low-refractive-index materials are alternately stacked, the high refractive index material includes six layers, and the low refractive index material includes five layers. The lower-refractive-index materials are SiO (n=1.46@550 nm, that is, a refractive index of light at a wavelength of 550 nm is 1.46), and the high-refractive-index materials are TiO₂ (n=2.35@500 nm). Each film layer is deposited by electron beam evaporation coating, with ion-assisted deposition. A deposition temperature of the electron beam evaporation coating is set at 120° C., and a vacuum degree is 1×10⁻³ Pa, a particle size of the low-refractive-index materials is 1-3 mm, and a particle size of the high-refractive-index materials is 3-5 mm. The energy is 150V and 3 A for SiO ion-assisted deposition, and the energy is 200 V and 6 A for TiO₂ ion-assisted deposition. An evaporation current for the fluorine-containing organic material is 100 mA.

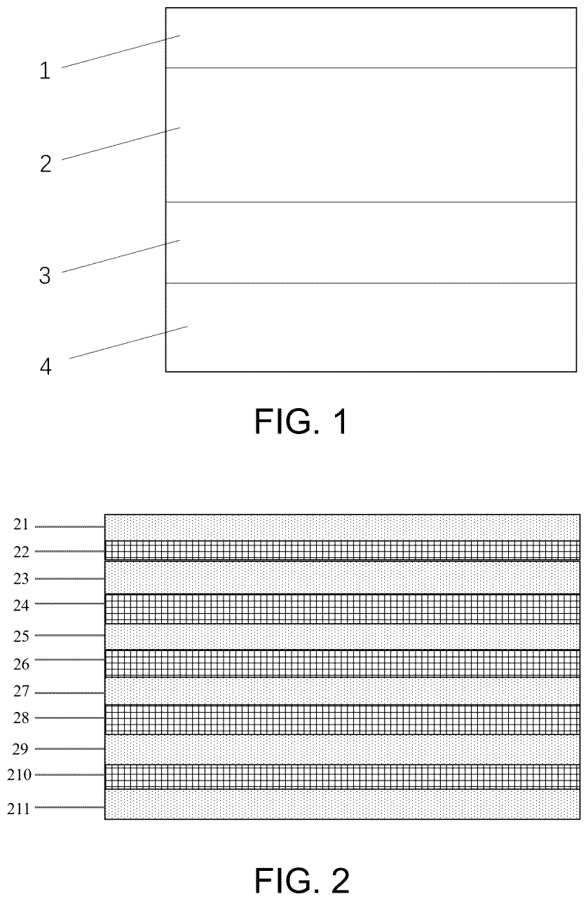

The film layers are arranged as shown in FIGS. 1 and 2. The spectrum regulation and control layer 3 includes a TiO₂ material layer 21, a SiO material layer 22, a TiO₂ material layer 23, a SiO material layer 24, a TiO₂ material layer 25, a SiO material layer 26, a TiO₂ material layer 27, a SiO material layer 28, a TiO₂ material layer 29, a SiO material layer 210, and a TiO₂ material layer 211.

Materials, thicknesses, and deposition rates of the film layers are shown in Table 1.

TABLE 1

| | | | Deposition |
|---|---|---|---|
| Layer No. | Materials | Thickness(nm) | rate (nm/s) |
| 21 | TiO₂ | 11 | 0.1 |
| 22 | SiO | 36 | 0.4 |
| 23 | TiO₂ | 113 | 0.8 |
| 24 | SiO | 173 | 1.0 |
| 25 | TiO₂ | 109 | 0.8 |
| 26 | SiO | 171 | 1.0 |
| 27 | TiO₂ | 103 | 0.8 |
| 28 | SiO | 178 | 1.0 |
| 29 | TiO₂ | 105 | 0.8 |
| 210 | SiO | 32 | 0.4 |
| 211 | TiO₂ | 14 | 0.1 |
| 1 | Fluorine-containing | 20 | 0.8 |
| | organic compound | | |

Hydrophobic performance testing was conducted on the organic encapsulation layer side of the radiative cooling protective film using a Theta contact angle analyzer (LSA100, LAUDA Scientific). The test results are shown in FIG. 6, an average static contact angle after deposition exceeded 140°.

### Example 2

The difference between Example 2 and Example 1 lies in the use of different materials for the spectrum regulation and control layer, as well as different thicknesses and deposition rates of each film layer, with details shown in Table 2.

TABLE 2

| | | | Deposition |
|---|---|---|---|
| Layer No. | Materials | Thickness(nm) | rate (nm/s) |
| 21 | Ti₂O₃ | 19 | 0.2 |
| 22 | SiO₂ | 46 | 0.3 |
| 23 | Ti₂O₃ | 103 | 0.6 |
| 24 | SiO₂ | 181 | 0.3 |
| 25 | Ti₂O₃ | 89 | 0.6 |
| 26 | SiO₂ | 164 | 0.8 |
| 27 | Ti₂O₃ | 114 | 0.6 |
| 28 | SiO₂ | 179 | 0.8 |
| 29 | Ti₂O₃ | 112 | 0.6 |
| 210 | SiO₂ | 41 | 0.8 |
| 211 | Ti₂O₃ | 11 | 0.2 |
| 1 | Fluorine-containing | 30 | 0.8 |
| | organic compound | | |

### Example 3

The difference between Example 3 and Example 1 lies in the number of layers as well as different thicknesses and deposition rates of each film layer, with details shown in Table 3.

TABLE 3

| | | | Deposition |
|---|---|---|---|
| Layer No. | Materials | Thickness (nm) | rate (nm/s) |
| 21 | TiO₂ | 11 | 0.1 |
| 22 | SiO | 36 | 0.4 |
| 23 | TiO₂ | 113 | 0.8 |
| 24 | SiO | 152 | 0.4 |
| 25 | TiO₂ | 109 | 0.8 |
| 26 | SiO | 171 | 1.0 |
| 27 | TiO₂ | 103 | 0.8 |
| 28 | SiO | 178 | 1.0 |
| 29 | TiO₂ | 105 | 0.8 |
| 210 | SiO | 31 | 0.4 |
| 211 | TiO₂ | 73 | 0.8 |
| 213 | SiO | 23 | 0.4 |
| 214 | TiO₂ | 16 | 0.1 |
| 1 | Fluorine-containing | 30 | 0.8 |
| | organic compound | | |

### Example 4

The difference between Example 4 and Example 1 lies only in the particle size of the materials. The low-refractive-index materials have a particle size of 5-8 mm, and the high-refractive-index materials have a particle size of 8-10 mm.

### Comparative Example 1

In Comparative Example 1, a tempered glass film for a mobile phone without a spectrum regulation and control layer, that is, the substrate film in Example 1, is provided.

The radiative cooling protective film in Example 1 and the tempered glass film for a mobile phone in Comparative Example 1 were subjected to the performance testing.

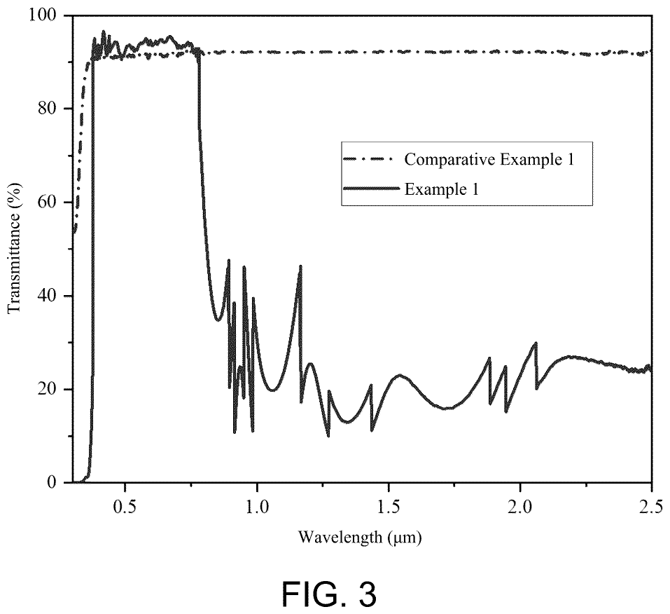

Reflectivities of the tempered glass film for a mobile phone in Comparative Example 1 and the radiative cooling protective film in Example 1 in a sunlight band were tested using an ultraviolet-visible-near infrared (UV-Vis-NIR) spectrophotometer (UV3600, Shimadzu Corporation) equipped with an integrating sphere attachment (ISR-3100). A measurement wavelength range was 0.3-2.5 μm. The results, as shown in FIG. 3, indicate that the radiative cooling protective film of Example 1 can further increase the transmittance in a visible light band from 0.90 to 0.94. Therefore, the radiative cooling protective film of the present disclosure enhances the transmittance of the tempered glass film for mobile phone. In the near-infrared band, the reflectivity is significantly improved, increasing from less than 0.1 for the original tempered glass film to greater than 0.8, thereby preventing the mobile phone from overheating due to a high ambient temperature.

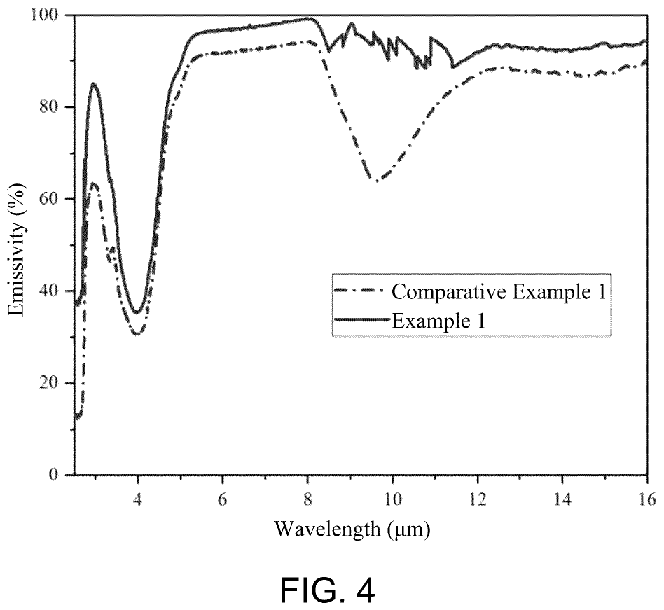

Emissivities of the tempered glass film for a mobile phone in Comparative Example 1 and the radiative cooling protective film of Example 1 were measured and compared using a Fourier transform infrared (FT-IR) spectrometer (Nicolet IS50, ThermoFisher), a gold-coated integrating sphere (IntergatIR MIR, Pike) and a mercury cadmium telluride MCT detector. As shown in FIG. 4, the radiative cooling protective film significantly enhances the emissivity in the mid-to-far infrared band, particularly in the atmospheric window (8-13 μm), where the emissivity is increased from less than 0.7 for the original glass to greater than 0.95. This demonstrates that the radiative cooling protective film of the present disclosure can effectively dissipate heat generated by the mobile phone into an external environment, thereby preventing the mobile phone from overheating.

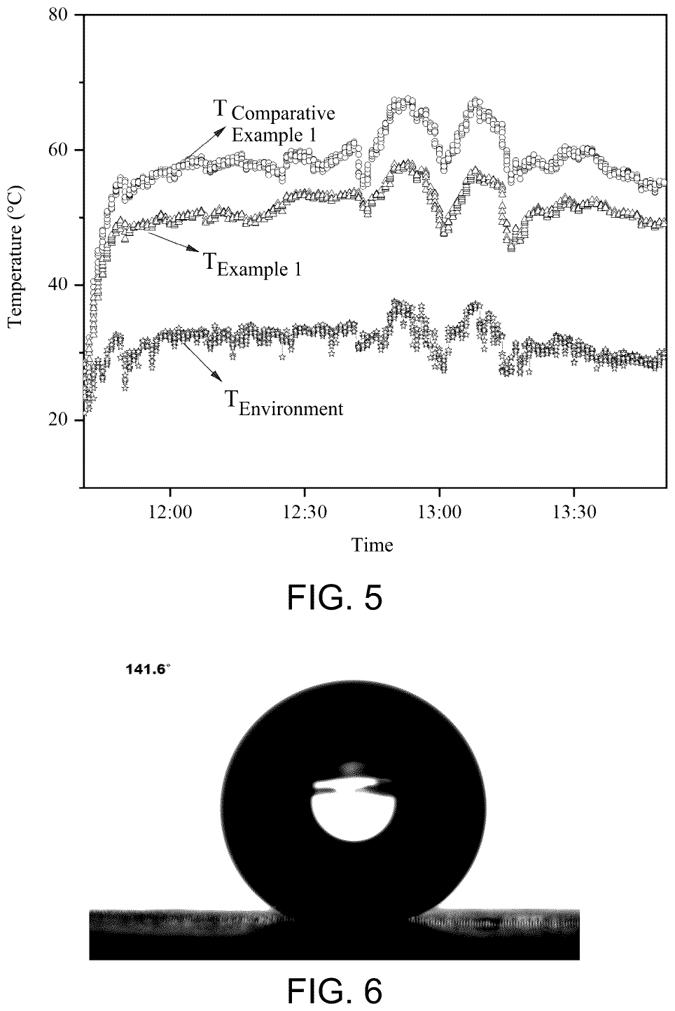

A temperature comparison test was conducted between the tempered glass film for a mobile phone in Comparative Example 1 and the radiative cooling protective film of Example 1. Specifically, temperature sensors were placed on the radiative cooling protective film, on the tempered glass film for a mobile phone (adhered to a commercially available mobile phone operating with the screen continuously on) and in ambient air, respectively. Temperature changes under the three conditions were recorded, lower temperatures indicate better cooling performance. A K-type thermocouple (Omega) was used. As shown in FIG. 5, under outdoor conditions at an ambient temperature of approximately 30° C., the radiative cooling protective film can reduce an operating temperature of the mobile phone by 5-10° C., exhibiting a significant radiative cooling effect.

### Comparative Example 2

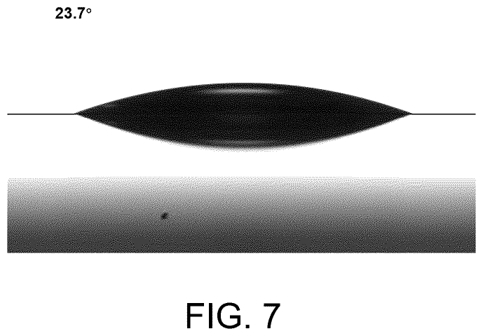

The difference between Comparative Example 2 and Example 1 lies in the absence of the fluorine-containing organic compound layer 1. Hydrophobic performance testing was conducted on the radiative cooling protective film using a Theta contact angle analyzer (LSA100, LAUDA Scientific). The test results are shown in FIG. 7, a contact angle of the glass after deposition was only 23.7°. This demonstrates that the fluorine-containing organic compound layer greatly improves the overall hydrophobicity of the film, thereby ensuring anti-fouling performance and wear resistance during use.

### Comparative Example 3

The difference between Comparative Example 3 and Example 1 lies in the particle size of the materials. Particle sizes of both the low-refractive-index materials and the high-refractive-index materials were 0.5-1 mm.

Performance testing was conducted on the radiative cooling protective films of Examples 1, 2, 4, and 5, as well as Comparative Examples 2 and 3. The results are shown in Table 4.

TABLE 4

| | | | Mid- and | Cooling | Water | |
|---|---|---|---|---|---|---|
| | Visible light | Near-infrared | far-infrared | effect | contact | Film |
| | transmittance | reflectivity | emissivity | (° C.) | angle (°) | cracking |
| Example 1 | 0.94 | 0.8 | 0.95 | 9.6 | 141.6 | No |
| Example 2 | 0.93 | 0.78 | 0.94 | 9.1 | 132.1 | No |
| Example 4 | 0.93 | 0.75 | 0.91 | 8.3 | 134.7 | No |
| Example 5 | 0.95 | 0.71 | 0.92 | 8.7 | 131.0 | No |
| Comparative | 0.95 | 0.79 | 0.94 | 7.3 | 23.7 | No |
| Example 2 | | | | | | |
| Comparative | 0.81 | 0.78 | 0.85 | 5.6 | 126.5 | No |
| Example 3 | | | | | | |

The above embodiments are merely intended for describing the technical solutions of the present disclosure rather than limiting same. Although the present disclosure is described in detail with reference to the above embodiments, persons of ordinary skill in the art should understand that they may still make modifications or equivalent replacements to the technical solutions of the present disclosure without departing from the spirit and scope of the technical solutions of the present disclosure.

What is claimed is:

1. A high-transmittance radiative cooling protective film, comprising a spectrum regulation and control layer, wherein the spectrum regulation and control layer comprises low-refractive-index materials and high-refractive-index materials which are alternately stacked; the high-transmittance radiative cooling protective film further comprising an organic encapsulation layer, a substrate film, and an adhesive layer, wherein the organic encapsulation layer is a hydrophobic layer, the substrate film is a tempered glass film, the organic encapsulation layer and a radiative cooling layer are respectively disposed on either side of the substrate film, and the adhesive layer is used to adhere the high-transmittance radiative cooling protective film to an electronic screen; the radiative cooling layer is the spectrum regulation and control layer; a top layer and a bottom layer of the spectrum regulation and control layer are both made of the high-refractive-index materials; the high-refractive-index materials in each layer are identical or different, and are selected from one or more of TiO₂, Ti₃O₅, Ti₂O₃, ZrO₂, CeO₂ and HfO₂; and the low-refractive-index materials in each layer are identical or different, and are selected from one or more of SiO₂, SiO, SiC, Al₂O₃, AlF₃ and MgF₂; both the low-refractive-index materials and the high-refractive-index materials are deposited by electron beam evaporation coating, and a coating process meets: a particle size of materials during deposition is 1-20 nm; and
thicknesses of material layers of the spectrum regulation and control layer are in the following order from a glass substrate outward: 10-20 nm, 20-50 nm, 100-150 nm, 150-200 nm, 80-110 nm, 150-200 nm, 90-130 nm, 150-200 nm, 90-130 nm, 20-50 nm, and 10-20 nm; and after light passes through the spectrum regulation and control layer, visible light has a transmittance exceeding 90%.

2. The high-transmittance radiative cooling protective film according to claim 1, wherein after light passes through the spectrum regulation and control layer, near-infrared light has a blocking ratio exceeding 80%, and mid-infrared light has an emissivity exceeding 95%.

3. The high-transmittance radiative cooling protective film according to claim 1, wherein the coating process meets one or more of following conditions:
a deposition rate of 0.1-1.0 nm/s;
a deposition temperature of 80-200° C.;
a vacuum level maintained at 1×10⁻²-1×10⁻⁴ Pa during deposition;
ion-assisted deposition used for deposition, with ion source energy parameters of a voltage of 150-220 V and a current of 3-6 A.

4. The high-transmittance radiative cooling protective film according to claim 1, wherein the spectrum regulation and control layer comprises, in sequence from the bottom layer to the top layer, TiO₂, SiO, TiO₂, SiO, TiO₂, SiO, TiO₂, SiO, TiO₂, SiO, and TiO₂.

5. The high-transmittance radiative cooling protective film according to claim 1, wherein the spectrum regulation and control layer comprises the following material layers arranged in sequence:
a TiO₂ material layer having a thickness of 10-20 nm;
a SiO material layer having a thickness of 20-50 nm;
a TiO₂ material layer having a thickness of 100-150 nm;
a SiO material layer having a thickness of 150-200 nm;
a TiO₂ material layer having a thickness of 80-110 nm;
a SiO material layer having a thickness of 150-200 nm;
a TiO₂ material layer having a thickness of 90-130 nm;
a SiO material layer having a thickness of 150-200 nm;
a TiO₂ material layer having a thickness of 90-130 nm;
a SiO material layer having a thickness of 20-50 nm; and
a TiO₂ material layer having a thickness of 10-20 nm.
